(19) United States
(12) Patent Application Publication
(10) Pub. No.: US 2013/0168720 A1
(43) Pub. Date: Jul. 4, 2013

(54) Optoelectronic Device

(71) Applicants: Andreas Biebersdorf, Regensburg (DE); Krister Bergenek, Regensburg (DE); Juergen Moosburger, Regensburg (DE)

(72) Inventors: Andreas Biebersdorf, Regensburg (DE); Krister Bergenek, Regensburg (DE); Juergen Moosburger, Regensburg (DE)

(73) Assignee: OSRAM OPTO SEMICONDUCTORS GMBH, Regensburg (DE)

(21) Appl. No.: 13/807,594

(22) PCT Filed: Jun. 29, 2011
(86) PCT No.: PCT/EP11/60931

§ 371 Date: Mar. 18, 2013

(30) Foreign Application Priority Data
Jun. 30, 2010 (DE) 10 2010 025 608.0

(51) Int. Cl. H01L 33/50

(52) U.S. Cl. CPC H01L 33/50
USPC 257/98

(57) ABSTRACT

An optoelectronic component includes at least one radiation-emitting semiconductor element. At least one converter element is used to convert the electromagnetic radiation emitted by the semiconductor element. At least one filter element, which includes filter particles or is formed by the same, scatters and/or absorbs at least one pre-definable wavelength range of the electromagnetic radiation emitted by the semiconductor element more strongly than a wavelength range that is different from the predefined wavelength range. The filter particles have a d50 value, measured in Q0, of at least 0.5 nm to no more than 500 nm and/or the filter particles are designed at least in some areas in a thread-like manner and in a thread-like region have a diameter that is at least 0.5 nm and no more than 500 nm.

This patent application is a national phase filing under section 371 of PCT/EP2011/060931, filed Jun. 29, 2011, which claims the priority of German patent application 10 2010 025 608.0, filed Jun. 30, 2010, each of which is incorporated herein by reference in its entirety.

### TECHNICAL FIELD

An optoelectronic device is specified.

### SUMMARY OF THE INVENTION

In one embodiment an optoelectronic device emits electromagnetic radiation in a pre-defineable wavelength range.

In accordance with at least one embodiment of the optoelectronic device, the device comprises at least one radiation-emitting semiconductor component. By way of example, the semiconductor component is a radiation-emitting semiconductor chip. The radiation-emitting semiconductor chip can be a luminescence diode chip, for example. The luminescence diode chip can be a light-emitting or laser diode chip that emits radiation in the range from ultraviolet to infrared light. Preferably, the luminescence diode chip emits light in the visible or ultraviolet range of the spectrum of the electromagnetic radiation. By way of example, the radiation-emitting semiconductor component is applied on a carrier, such as, for example, a circuit board or a leadframe. The device is surface-mountable, for example.

In accordance with at least one embodiment of the optoelectronic device, the latter comprises at least one converter element, which serves for converting the electromagnetic radiation emitted by the semiconductor component. By way of example, the converter element is disposed downstream of the semiconductor component along a radiation exit path of the optoelectronic device. The radiation exit path is the path of the electromagnetic radiation from emission by the semiconductor component to the coupling-out of the electromagnetic radiation from the device. The at least one converter element converts light of one wavelength into light of another wavelength. By way of example, the at least one converter element converts blue light primarily emitted by the semiconductor component partly into yellow light which can mix together with the blue light to form white light. Therefore, the at least one converter element has the function of a light converter during the operation of the optoelectronic device.

In accordance with at least one embodiment of the optoelectronic device, the latter comprises at least one filter element or filter means, which comprises filter particles or is formed with the latter. By way of example, the filter element is disposed downstream of the converter element along the radiation exit path.

In accordance with at least one embodiment, the filter element scatters and/or absorbs at least one pre-definable wavelength range of the electromagnetic radiation emitted by the semiconductor component to a greater extent than a wavelength range that is different than the predefined wavelength range. The filter element can scatter and/or absorb the radiation unconverted by the converter element in a wavelength-selective manner.

In accordance with at least one embodiment, the filter particles have a d₅₀ value, measured in Q₀, of at least 0.5 nm to at most 500 nm, preferably at least 10 nm to at most 200 nm, and/or are embodied in thread-like fashion at least in places and have in a thread-like region a diameter that is at least 0.5 nm and at most 500 nm. By way of example, the d₅₀ value is 1 nm to 2 nm. In this case, the term “d₅₀” concerns a median diameter of the filter particles, and the term “Q₀” concerns a cumulative number distribution of the filter particles. Both terms are defined by the standard ISO 9276-2 “Representation of results of particle-size analysis—part 2: calculation of average particle sizes/diameters and moments from particle-size distributions.” In this context “thread-like” means that the extent of the filter particles in a main extension direction is significantly greater than the diameter of the filter particles. “Diameter” is, for example, the extent of the filter particles in a direction perpendicular to the main extension direction. In this case, “significantly greater” means that the extent in the main extension direction is at least double the magnitude of the diameter of the filter particles.

It has been found that filter particles having such a dimensioning make it possible to set as precisely as possible the pre-definable wavelength range which is intended to be scattered and/or absorbed by the filter element to a greater extent. In particular, such filter particles are particularly suitable for scattering and/or absorbing visible light or electromagnetic radiation in the ultraviolet range.

In this case, the optoelectronic device described here is based, inter alia, on the insight that, for incorporating the optoelectronic device in flashing lights and/or in traffic lights, for example, the optoelectronic device is intended to emit electromagnetic radiation in a pre-definable and selected wavelength range. However, electromagnetic radiation emitted by a radiation-emitting semiconductor component of the device is only just partly converted into the desired wavelength range by a converter element of the device. At least part of the electromagnetic radiation emitted by the radiation-emitting semiconductor component is not converted by the converter element. The unconverted, undesired radiation portion can mix with the converted, desired radiation portion when the electromagnetic radiation emerges from the optoelectronic device. Such mixed light has, however, a shifted color locus in comparison with the desired wavelength range.

In the present case, the filter element scatters and/or absorbs the pre-definable, for example the undesired, wavelength range from the entire wavelength range emitted by the radiation-emitting semiconductor component, such that the filter element acts as a “filter.” Such an optoelectronic device advantageously emits electromagnetic radiation only in the range of a desired spectrum of the electromagnetic radiation. In this respect, such an optoelectronic device can advantageously be used for specific applications, for example in flashing lights and/or in traffic lights.

In accordance with at least one embodiment the converter element comprises converter particles or is formed with the latter and the semiconductor component is covered at least in places in a positively locking manner by a radiation-transmissive potting at exposed places, wherein the filter particles and the converter particles are introduced into the potting. That is to say that the material of the potting—the potting compound—is in direct contact with the radiation-emitting semiconductor component at least in places. In particular, both the converter particles and the filter particles are distributed randomly, that is to say non-deterministically, in the potting. In this context, “radiation-transmissive” means that the shaped body is transmissive to electromagnetic radiation at least to the extent of 80%, preferably to the extent of more than 90%.

In accordance with at least one embodiment of the optoelectronic device, the filter element is disposed downstream of the converter element in an emission direction of the semiconductor component and is in at least indirect contact with said converter element. By way of example, the filter element is an optical element, such as, for example, a lens or a covering plate. The optical element can then be applied, for example adhesively bonded, directly onto an outer area of the converter element facing away from the radiation-emitting semiconductor component.

In accordance with at least one embodiment of the optoelectronic device, the filter particles are formed with at least one of the following materials or with at least one chemical compound of the following materials: Cd, Td, Si, Ag, Au, Fe, Pt, Ni, Se, S, SiO₂, TiO₂, Al₂O₃, Fe₂O₃, Fe₃O₄, ZnO. In principle, even further semiconductor materials or metals are appropriate for the filter particles. Likewise, the filter particles can be formed with a dielectric material. It is possible to use semiconductor materials whose band gap can for example be set by the particle size, for example by the d₅₀ value of the particles and/or the diameter thereof, individually to the desired scattering and/or absorption properties of the filter particles. Furthermore, it is possible to use metals which are selected according to their plasmon resonance relevant to the scattering and/or absorption properties. It has been possible to show that filter particles formed by means of such materials have a particularly narrow absorption spectrum, in particular in the ultraviolet and/or visible range of the spectrum of electromagnetic radiation. As a result, the predefined, undesired wavelength range can be selected particularly precisely by means of the filter particles, whereby as little of the desired wavelength range as possible is absorbed and/or scattered. In other words, the filter particles formed by means of such materials have a narrowly defined Plasmon resonance. Moreover, such filter particles can be produced particularly simply from chemical syntheses. Furthermore, the filter particles formed with such materials are thermally stable, as a result of which neither an absorption and/or scattering shift nor other aging phenomena of the filter particles occur during the operation of the optoelectronic device. Furthermore, these filter particles enable simple application (also processing), for example onto the converter element, since the filter particles are present in solution for application.

In accordance with at least one embodiment, the filter particles comprise a core formed with a first material, wherein the core is encapsulated with an envelope at least in places, wherein the envelope is formed with a second material and is in direct contact with the core. In other words, the filter particles are then formed by a composite structure. Filter particles configured in this way advantageously make it possible to combine the optical absorption and/or scattering properties of the individual materials in an individual filter particle with one another and to coordinate them with the respective requirements of the user.

In accordance with at least one embodiment, the core is formed with SiO₂ as the first material and the envelope is formed with Au and/or Ag as the second material. It has been found that filter particles formed with such materials the absorption and/or scattering range can be particularly narrowly delimited and set precisely.

It is also conceivable for the envelope to be formed with a plurality of individual layers which, proceeding from the core, succeed one another in a pre-definable order in a direction away from the core. By way of example, the layer sequence proceeding from the core in a direction away from the core is formed by the layer sequence Au, SiO₂, Ag. By way of example, the core is then formed with SiO₂.

Furthermore, it is conceivable for the transition from the core to the envelope to be gradual. That is to say that a transition zone can form between the core and the envelope, both materials that adjoin one another, that of the core and that of the envelope, being situated in said transition zone. The core and the envelope then cannot be sharply demarcated from one another in said transition zone and merge into one another uniformly, for example, in the transition zone.

In accordance with at least one embodiment, the device emits electromagnetic radiation which lies on a spectral color line of a CIE standard chromaticity diagram. Such a device is advantageously suitable for specific applications in which, as a result of specific requirements made of the device, only one spectral color is used or is permitted to be emitted.

In accordance with at least one embodiment of the optoelectronic device, color coordinates cₓ and c_{y} of the electromagnetic radiation emitted by the semiconductor component differ from the color coordinates of the electromagnetic radiation emitted by the device by at least 0.005 in each case. After the conversion of the electromagnetic radiation emitted by the radiation-emitting semiconductor component by the converter element, the color coordinates of the radiation reemitted by the converter element together with the unconverted radiation lie within the color space on an area which is bordered and enclosed by the spectral color line of the CIE standard chromaticity diagram. In other words, this electromagnetic radiation is mixed light. If electromagnetic radiation of a pre-defineable wavelength range is then selected out by the filter element, the electromagnetic radiation “freed” of such a wavelength range can be one spectral color. In other words, the filter element brings about a shift in the color coordinates by at least 0.005 to a color locus of a spectral color lying on the spectral color line of the CIE standard chromaticity diagram. By way of example, the shift is at most 0.01.

In accordance with at least one embodiment, the filter particles are formed with Au and have a d₅₀ value, measured in Q₀, of at least 1 nm to at most 200 nm, preferably at least 10 nm to at most 160 nm, wherein the filter element scatters and/or absorbs electromagnetic radiation in the wave range, of at least 530 nm to at most 770 nm to a greater extent than a wavelength range that is different therefrom. By way of example, the semiconductor component emits green light, which is partly converted into red light by the converter element. The green light not converted by the converter element can be scattered and/or absorbed by means of the filter particles. Optoelectronic semiconductor components which emit green light can advantageously be operated with a lower operating voltage, which can lead to more cost-effective operation of the optoelectronic device.

In accordance with at least one embodiment the filter particles are formed with Ag and have a d₅₀ value, measured in Q₀, of at least 1 nm to at most 200 nm, preferably at least 20 nm to at most 80 nm, wherein the filter element scatters and/or absorbs electromagnetic radiation in the wave range of at least 430 nm to at most 490 nm to a greater extent than a wavelength range that is different therefrom. By way of example, the wavelength range absorbed and/or scattered by the filter element is blue light. The electromagnetic radiation emitted by the device can then be free of the blue light.

It is likewise conceivable for the semiconductor component to emit ultraviolet radiation, for example in the near ultraviolet range. By way of example, the converter element comprises at least two, for example three different conversion means with which the converter particles are in each case formed. By way of example, the converter particles formed with a first conversion substance convert the ultraviolet radiation emitted by the radiation-emitting semiconductor component partly into red light and the other two converter particles, formed with a different conversion substance in each case, convert the ultraviolet radiation emitted by the radiation-emitting semiconductor component partly into blue and green light. Red, blue and green light can then be mixed to form white light. However, the converter element only partly converts the ultraviolet radiation into white light. The portion of the ultraviolet electromagnetic radiation not converted by the converter element can, for example, impinge in the human eye of an observer of the device and cause damage in the observer's eye there on account of its short-wave nature. Advantageously, the filter element now selectively absorbs and/or scatters the undesired ultraviolet radiation portion out, such that the optoelectronic device only emits white light that is safe for the human eye.

Furthermore, a flashing light is specified.

In accordance with at least one embodiment, the flashing light comprises an optoelectronic device as described in one or more of the embodiments described here. That is to say the features presented for the optoelectronic device described here are also disclosed for the flashing light described here.

In accordance with at least one embodiment, the flashing light comprises a projection area, on which the electromagnetic radiation coupled out from the optoelectronic device impinges. By way of example, the projection area is an at least partly radiation-transmissive screen. By way of example, said screen is then integrated into a reflection and/or radiation coupling-out unit. If the radiation-emitting semiconductor component emits blue light, for example at a wavelength of 440 nm, the converter element converts only part of the blue light into, for example, orange or yellow light. It is conceivable that approximately 1 to 10%, for example, 1 to 5% of the blue light emitted by the radiation-emitting semiconductor component is not converted by the converter element. Advantageously, the filter element scatters and/or absorbs the unconverted, undesired blue light, such that the optoelectronic device only emits the light converted to orange or yellow light by the converter element. This converted light can then impinge on the projection area and can be coupled out by the latter at least partly from the flashing light. Through the filter property of the filter element, the specific specification requirements made of the flashing light can be individually set depending on stipulation or application.

### BRIEF DESCRIPTION OF THE DRAWINGS

The optoelectronic device described here and the flashing light described here are explained in greater detail below on the basis of exemplary embodiments and the associated Figures.

FIGS. 1A to 1D show, in schematic side views, exemplary embodiments of an optoelectronic device described here;

FIGS. 2A to 2D show individual radiation measurement curves;

FIGS. 3A to 3C show, in schematic sectional illustrations, different exemplary embodiments of the filter particles described here; and

FIGS. 4A and 4B show in schematic side views an exemplary embodiment of a flashing light described here.

In the exemplary embodiments and the Figures, identical or identically acting constituent parts are respectively provided with the same reference signs. The elements illustrated should not be regarded as true to scale; rather, individual elements may be illustrated with an exaggerated size in order to afford a better understanding.

### DETAILED DESCRIPTION OF ILLUSTRATIVE EMBODIMENTS

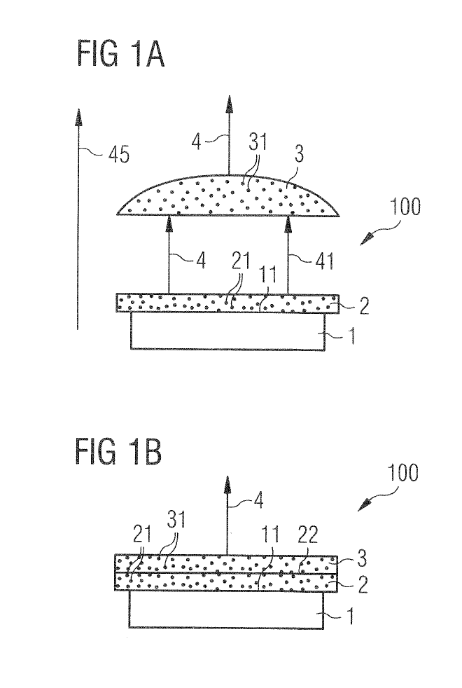

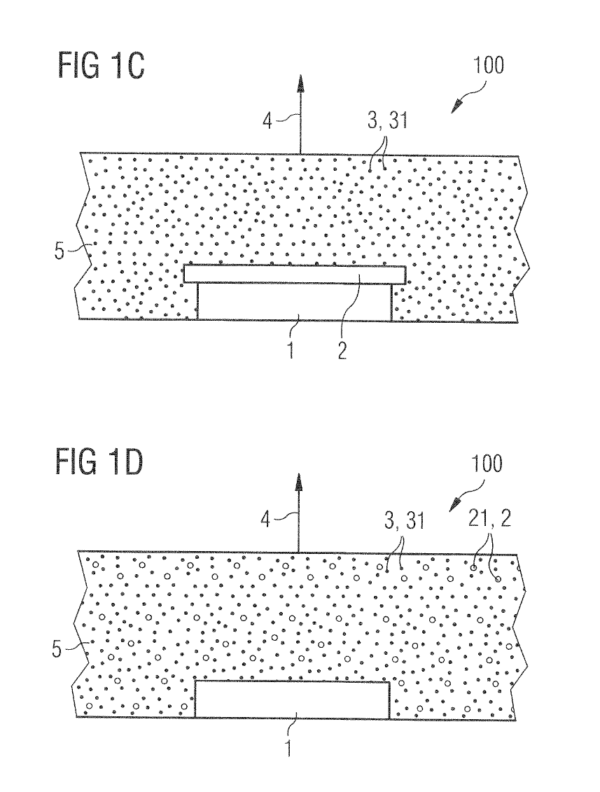

FIG. 1A shows, on the basis of a schematic side view, an optoelectronic device 100 described here, comprising a radiation-emitting semiconductor component 1. In the present case, the radiation-emitting semiconductor component 1 is a radiation-emitting semiconductor chip that emits blue light at a wavelength of 440 nm. A converter element 2 is adhesively bonded onto a radiation exit area 11 of the semiconductor component 1. Converter particles 21 for converting the light emitted by the semiconductor component 1 are introduced into the converter element 2.

The filter element 3 is not in direct contact with the converter element 2, but rather is arranged in a manner spaced apart from the converter element 2 and is disposed downstream of the converter element 2 in the emission direction 45. It can be discerned that the radiation emerging from the converter element 2 is composed of a desired wavelength range 4 converted by the converter element 2 and an undesired wavelength range 41 not converted by the converter element 2. In the present case, the undesired wavelength range 41 is the blue light not fully converted by the converter element 2, wherein approximately 10% of the blue light emitted by the radiation-emitting semiconductor component 1 is not converted by the converter element 2.

Furthermore, an outer area of the filter element 3 facing away from the converter element 2 is embodied in lens-shaped fashion, as a result of which a radiation coupling-out efficiency of the optoelectronic device 100 is advantageously increased. Furthermore, it can be discerned in FIG. 1A that the filter element 3 absorbs the undesired wavelength range 41, that is to say the blue light, such that only the desired wavelength range 4, for example orange light, is still coupled out from the optoelectronic device 100.

The filter element 3 can be formed with an epoxide, a silicone, a mixture of silicone and epoxide or a transparent ceramic material. Filter particles 31 in accordance with one of the embodiments mentioned above are introduced into the filter element 3. The filter element 3 can also be formed with some other plastics material, for example PMMA.

It is likewise conceivable for a quantitative proportion of filter particles 31 to consist of silver, and a further quantitative proportion to consist of gold. In this respect, the undesired wavelength range 41 can advantageously be set individually by means of such a mixture.

FIG. 1B shows a further exemplary embodiment of an optoelectronic device 100 described here, wherein, in contrast to FIG. 1A, the filter element 3 is in direct contact with the converter element 2. By way of example, for this purpose the converter element 2 is adhesively bonded, or applied by means of screen printing or blade coating, onto an outer area 22 of the converter element 2.

FIG. 1C illustrates, in a schematic side view, how a radiation-transmissive potting 5 covers both the radiation-emitting semiconductor component 1 and the converter element 2, in the present case a lamina, also referred to as plate, or a film, also referred to as foil, in a positively locking manner at all exposed places. The filter particles 31 are introduced into the potting 5. In the present case, therefore, the filter particles 31 form the filter element 3.

In FIG. 1D, in comparison with the optoelectronic device 100 illustrated in FIG. 1C, converter particles 21 form the converter element 2. In other words, the lamina- or film-like shaping of the converter element 2 is dispensed with in FIG. 1D.

For this purpose, the converter particles 21 together with the filter particles 31 are introduced into the potting 5. Both the converter particles 21 and the filter particles 31 are distributed randomly, that is to say not deterministically, in the shaped body 5.

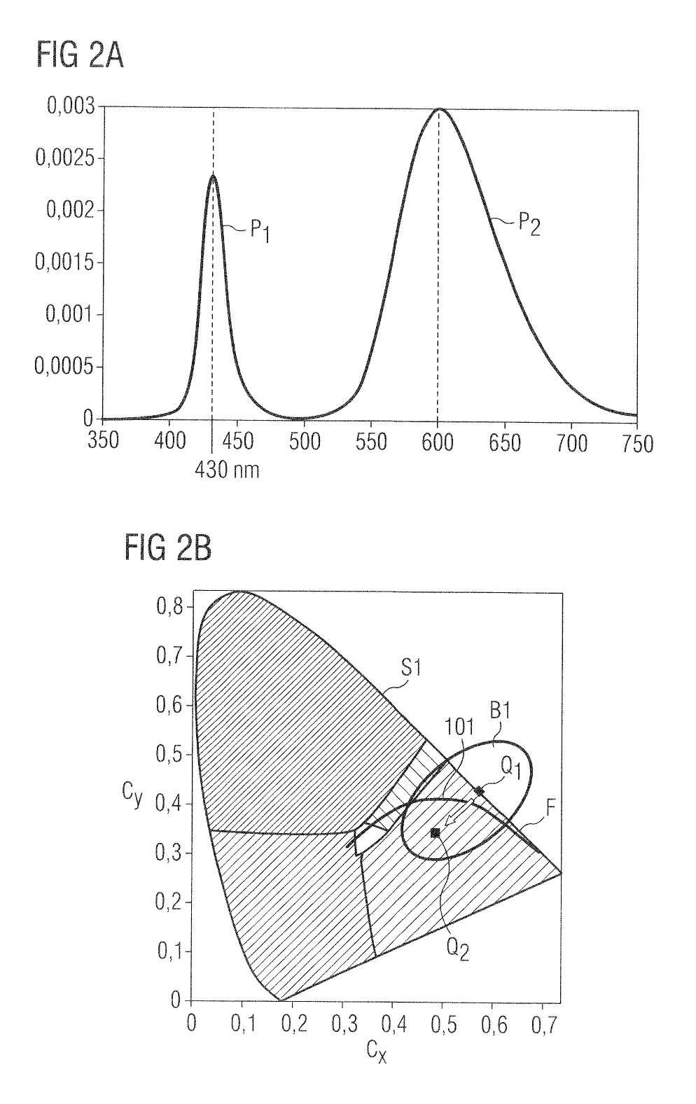

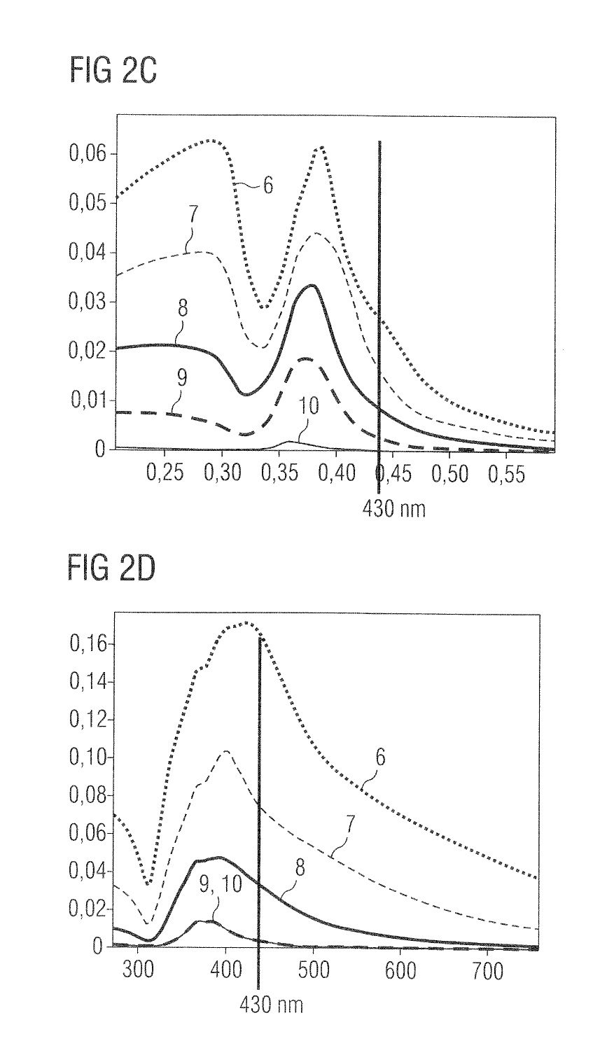

FIG. 2A illustrates an intensity distribution of the electromagnetic radiation emerging from the converter element 2 as a function of the wavelength, wherein the physical unit of the intensity distribution is normalized to one. It can be discerned that the electromagnetic radiation emerging from the converter element 2 has two maxima at 430 nm and at 600 nm. In the present case, the excursion P1 concerns blue light and the excursion P2 concerns orange light. In other words, mixed light composed of the orange light and the blue light emerges from the converter element 2. In the present case, 11% of the blue light emitted by the radiation-emitting semiconductor component 1 is not converted into orange light by the converter element. In other words, the mixed light has the undesired wavelength range of the blue light at 430 nm.

FIG. 2B shows, on a CIE standard chromaticity diagram F, respective color coordinates C_{y} and Cₓ of the color locus Q₂ of the light emerging from the converter element 2 and a color locus Q₂ of the light emitted by the optoelectronic device 100, wherein the undesired wavelength range 41, that is to say the blue light, has already been filtered out by the filter element 3.

Furthermore, FIG. 2B illustrates a spectral color line S on which the color locus Q₁ is situated. The influence of the color locus shift of the filter element 3 can be discerned in FIG. 2B. In the present case, the color coordinates Cₓ and C_{y} of the color locus Q₂ shift in the direction of the color coordinates of the color locus Q₁. In this case, the respective shift is 0.07 in the Cₓ coordinate and 0.1 in the C_{y} coordinate. By means of the filter element 3, therefore, the color locus coordinate of the optoelectronic device 100 can be shifted, for example, within the region B1 from the point Q₂ to the point Q₁, which lies on the spectral color line S. In other words, a color locus shift proceeding from the point Q₁ in the direction of the point Q₂ crosses a black body curve 101.

FIG. 2C illustrates an absorption scattering cross section of the filter element 3 as a function of the wavelength incident on the filter element 3. The individual measurement curves 6, 7, 8, 9 and 10 correspond to the respective d₅₀ values of the spherical filter particles 31 of 90 nm, 70 nm, 50 nm, 30 nm and 10 nm. The physical unit of the absorption scattering cross section of the curves 6, 7, 8, 9 and 10 is normalized to one. In the present case, the filter particles 31 are formed with Ag and introduced into a material having a refractive index of 1.5. By way of example, the material is the shaped body compound of the shaped body 5 in accordance with the exemplary embodiments in FIGS. 1C and 1D. At a wavelength of 430 nm, that is to say within the wavelength range of blue light, the curve 6 has the highest absorption scattering cross section. In other words, electromagnetic radiation of 430 nm can be absorbed particularly effectively by the filter element 3 if filter particles 31 having a d₅₀ value of 90 nm are introduced into the filter element 3.

FIG. 2D illustrates the corresponding curves 6, 7, 8, 9 and 10 for the scattering cross section as a function of the wavelength. It can once again be discerned that the curve 6 has the highest scattering cross section at a wavelength of 430 nm. Furthermore, it can be discerned that the scattering cross section of the curve 6 at a wavelength of 430 nm is approximately double the magnitude of the scattering cross section of the curve 7 at such a wavelength. It can likewise be discerned that the scattering cross section of the curve 8 is also approximately half of the scattering cross section of the curve 7 and respectively approximately a quarter of the scattering cross section of the curve 6. The curves 9 and 10 in turn have the lowest scattering cross sections in each case, wherein it can be discerned that the two scattering cross sections of the curves 9 and 10 are virtually superimposed.

In this respect, the curve 6 exhibits the highest absorption and scattering properties, as a result of which the electromagnetic radiation of the wavelength 430 nm, that is to say the blue light, can be filtered out particularly effectively with particles having a d₅₀ value of 90 nm.

For technical applications of the optoelectronic device it may be advantageous to absorb as much of the blue light as possible and to scatter as little of the blue light as possible. A quantitatively proportional mixture of different filter particles made of different sizes and/or materials may then be appropriate. In other words, the absorption and scattering properties can be set by means of the filter particles 31 of the filter element 3.

For the curve 6 the same applies to filtering out ultraviolet radiation emitted by the radiation-emitting semiconductor component 1. It can be gathered from the curves in FIGS. 2C and 2D that the curve 6 also exhibits the highest absorption and scattering properties with regard to ultraviolet radiation. In this respect, damage to the human eye of an observer of the optoelectronic device 100 can advantageously be avoided since the portion of ultraviolet radiation emitted by the optoelectronic device 100 is minimized.

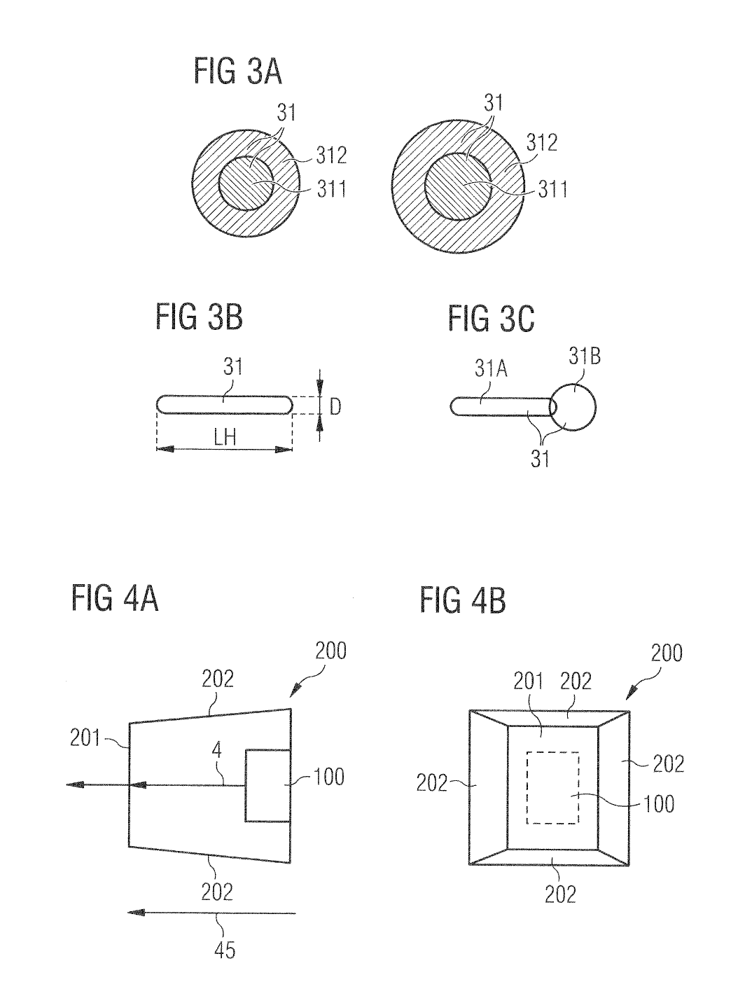

FIG. 3A shows, in a schematic sectional illustration, filter particles 31 formed with a core 311, which is completely encapsulated by an envelope 312, wherein the envelope 312 is in direct contact with the core 311. In the present case, the core 311 is formed with silicon dioxide, wherein the envelope 312 is formed with Au. Such filter particles 31 form composite particles by means of which the absorption and/or scattering properties of the individual materials in combination with one another can be combined in a filter particle 31.

FIG. 3B illustrates, in a schematic sectional illustration, filter particles 31 embodied completely in thread-like fashion. The filter particles 31 have a diameter D that is at least 0.5 nm and at most 500 nm, for example 1 nm. In the present case an extent of the filter particles 31 in a main extension direction LH is at least double the diameter D, for example one millimeter or more. By way of example, the filter particles 31 are formed with Au.

FIG. 3C illustrates a further embodiment of the filter particles 31 in a schematic sectional illustration. The filter particles 31 are in each case formed with a thread-like region 31A and a sphere-like region 31B. By way of example, the thread-like region 31A is the filter particles 31 already described in FIG. 3B. By way of example, the sphere-like region 31B has a d₅₀ value of 1 nm or more. It can be discerned from FIG. 3C that the filter particles 31 are constructed in the shape of a dumbbell or rattle. The thread-like region 31A can be formed with Au and the sphere-like region 31B can be formed with Ag.

It is also conceivable for the filter particles 31 to be formed with a plurality of thread-like regions 31A and/or sphere-like regions 31B. Filter particles 31 formed with such regions can then form three-dimensional structures. It is conceivable for the filter particles 31 to be constructed in the form of a network, at the nodes of which the sphere-like regions 31B can be arranged. By way of example, the filter particles 31 are embodied in pyramidal or tetrahedral fashion. The sphere-like regions 31B can be arranged in the corners of such a three-dimensional structure, wherein the thread-like regions 31A are arranged between the spherical regions 31B and can connect the sphere-like regions 31B to one another. The thread-like regions 31A can then form side edges of the three-dimensional structure.

Furthermore the individual filter particles 31 can be formed at least in places by a wound structure having at least one principal axis. By way of example, the filter particles 31 are embodied in the form of a helix.

FIGS. 4A and 4B show, in schematic side views, a flashing light 200 described here.

The optoelectronic device 100, for example in accordance with one of the embodiments in FIG. 1C or 1D, emits electromagnetic radiation from the desired wavelength range 4 in the direction of a projection area 201. The desired wavelength range 4 is orange light. The radiation-emitting semiconductor component 1 emits blue light at a wavelength of 440 nm. The converter element 2 is an (Sr,Ba)2Si5N8 or a Ca-alpha-SiAlON converter that converts the blue light partly into orange light. Approximately 10% of the blue light emitted by the radiation-emitting semiconductor component 1 is not converted by the converter element 2. The unconverted blue light is absorbed by the filter particles 31 formed with Ag and having a d₅₀ value, measured in Q₀, of 30 nm, such that the radiation emitted by the optoelectronic device 100 is free of the blue light.

By way of example, the projection area 201 is formed with a glass or a radiation-transmissive plastic. The electromagnetic radiation emitted from the radiation-emitting semiconductor component 1 is at least partly coupled out from the flashing light via the projection area 201. Both the optoelectronic device 100 and the projection area 201 are bordered by at least one reflection body 202 in a direction transversely with respect to the radiation exit direction 45, wherein the reflection body 202 directs electromagnetic radiation impinging on it at least partly in the direction of the projection area 201.

FIG. 4B shows the flashing light 200 in the direction proceeding from the projection area 201 toward the optoelectronic device 100, that is to say opposite to the radiation exit direction 45. The optoelectronic device 100 is in turn illustrated by dashed lines, said optoelectronic device being concealed by the projection area 201.

The invention is not restricted by the description on the basis of the exemplary embodiments. Rather, the invention encompasses any novel feature and also any combination of features, which in particular includes any combination of features in the patent claims, even if this feature or this combination itself is not explicitly specified in the patent claims or the exemplary embodiment.

1-11. (canceled)

12. An optoelectronic device, comprising:
a radiation-emitting semiconductor component;
a converter element, configured to convert electromagnetic radiation emitted by the semiconductor component;
a filter element that comprises filter particles or is formed with the converter particles, wherein the filter element is configured to scatter and/or absorb a pre-definable wavelength range of the electromagnetic radiation emitted by the semiconductor component to a greater extent than a wavelength range that is different than the predefined wavelength range,
wherein the filter particles have a d₅₀ value, measured in Q₀, of at least 0.5 nm to at most 500 nm and/or wherein the filter particles are embodied in thread-like fashion at least in places and have in a thread-like region a diameter that is at least 0.5 nm and at most 500 nm.

13. The optoelectronic device according to claim 12, wherein the filter particles have a d₅₀ value, measured in Q₀, of at least 0.5 nm to at most 500 nm.

14. The optoelectronic device according to claim 12, wherein the filter particles are embodied in thread-like fashion at least in places and have in a thread-like region a diameter that is at least 0.5 nm and at most 500 nm.

15. The optoelectronic device according to claim 12, wherein the filter particles have a d₅₀ value, measured in Q₀, of at least 0.5 nm to at most 500 nm and wherein the filter particles are embodied in thread-like fashion at least in places and have in a thread-like region a diameter that is at least 0.5 nm and at most 500 nm.

16. The optoelectronic device according to claim 12, wherein the converter element comprises converter particles or is formed with converter particles and the semiconductor component is covered at least in places in a positively locking manner by a radiation-transmissive potting at exposed places, wherein the filter particles and the converter particles are disposed within the potting.

17. The optoelectronic device according to claim 12, wherein the filter element is disposed downstream of the converter element in an emission direction of the semiconductor component and is in indirect contact with the converter element.

18. The optoelectronic device according to claim 12, wherein the filter particles are formed with at least one of the following materials or with at least one chemical compound of the following materials: Cd, Td, Si, Ag, Au, Fe, Pt, Ni, Se, S, SiO₂, TiO₂, Al₂O₃, Fe₂O₃, Fe₃O₄, ZnO.

19. The optoelectronic device according to claim 12, wherein the filter particles comprise a core formed with a first material, wherein the core is encapsulated with an envelope at least in places, wherein the envelope is formed with a second material and is in direct contact with the core.

20. The optoelectronic device according to the claim 19, wherein the core is formed with SiO₂ as the first material and the envelope is formed with Au and/or Ag as the second material.

21. The optoelectronic device according to claim 12, wherein the device emits electromagnetic radiation that lies on a spectral color line of a CIE standard chromaticity diagram.

22. The optoelectronic device according to claim 12, wherein color locus coordinates cₓ and c_{y} of the electromagnetic radiation emitted by the semiconductor component differ from the color locus coordinates of the electromagnetic radiation emitted by the device by at least 0.005 in each case.

23. The optoelectronic device according to claim 12, wherein the filter particles are formed with Au and have a d₅₀ value, measured in Q₀, of at least 1 nm to at most 200 nm, wherein the filter element scatters and/or absorbs electromagnetic radiation in the wave range of at least 530 nm to at most 770 nm to a greater extent than a wavelength range that is different therefrom.

24. The optoelectronic device according to claim 12, wherein the filter particles are formed with Ag and have a d₅₀ value, measured in Q₀, of at least 1 nm to at most 200 nm, wherein the filter element scatters and/or absorbs electromagnetic radiation in the wave range of at least 430 nm to at most 490 nm to a greater extent than a wavelength range that is different therefrom.

25. A flashing light, comprising:
an optoelectronic device according to claim 12, and
a projection area, on which electromagnetic radiation coupled out from the optoelectronic device impinges.

26. An optoelectronic device, comprising:
a radiation-emitting semiconductor component;
a converter element, configured to convert electromagnetic radiation emitted by the semiconductor component;
a filter element that comprises filter particles or is formed with filter particles, wherein the filter element is configured to scatter and/or absorb a pre-definable wavelength range of the electromagnetic radiation emitted by the semiconductor component to a greater extent than a wavelength range that is different than the predefined wavelength range
wherein the filter particles have a d₅₀ value, measured in Q₀, of at least 0.5 nm to at most 500 nm and/or the filter particles are embodied in thread-like fashion at least in places and have in a thread-like region a diameter that is at least 0.5 nm and at most 500 nm,
wherein the filter particles comprise a core formed with a first material, wherein the core is encapsulated with an envelope at least in places, wherein the envelope is formed with a second material and is in direct contact with the core, and
the core is formed with SiO₂ as the first material and the envelope is formed with Au and/or Ag as the second material.
